(19) United States
(12) Patent Application Publication
(10) Pub. No.: US 2009/0085591 A1
(43) Pub. Date: Apr. 2, 2009

(54) PROBE TIP INCLUDING A FLEXIBLE CIRCUIT BOARD

(75) Inventors: Emad SOUBH, Camas, WA (US); Travis ELLIS, Portland, OR (US); Glenn MENEAR, Georgetown, IN (US)

Correspondence Address: SAMTEC INCORPORATED;C/O KEATING & BENNETT, LLP, 1800 Alexander Bell Drive, SUITE 200, Reston, VA, 20191, US

(73) Assignee: SAMTEC INC., New Albany, IN (US)

(21) Appl. No.: 12/242,682

(22) Filed: Sep. 30, 2008

Related U.S. Application Data
(60) Provisional application No. 60/976,788, filed on Oct. 1, 2007.

(51) Int. Cl. G01R 1/067

(52) U.S. Cl. 324/754

(57) ABSTRACT

A probe tip for attaching to a device to be tested includes a flexible circuit board, at least one contact pad arranged to be able to be attached to at least one contact of a probe tip connector, at least one electrical component having first and second ends, and at least one test pad arranged to be able to be attached to the device to be tested. The at least one contact pad is connected to the first end of the at least one electrical component, and the at least one test pad is connected to the second end of the at least one electrical component. Each of the electrical components of the probe tip is connected to at least one contact pad and is connected to at least one test pad.

### BACKGROUND OF THE INVENTION

1. Field of the Invention

The present invention relates to probe tips. More specifically, the present invention relates to probe tips including a flexible circuit board.

2. Description of the Related Art

It is currently known to test a device by soldering a lead of a resistor to an electrical path on the device so that electrical signals transmitted through the electrical path can be monitored and tested. This method has several drawbacks. First, if more than one electrical path needs to be tested, then a lead of a resistor must separately be soldered to each electrical path. Second, the electrical stub length, which is the length of the lead of the resistor soldered to the electrical path, is long and can be quite inconsistent between different resistors because a technician must cut the lead of each of the resistors soldered to the electrical path. Third, the leads of the resistor are stiff and prone to breaking. Fourth, the soldering of the leads of the resistor to the electrical path can damage or destroy the electrical path. Fifth, additional metal (i.e., the solder used to attach the lead of the resistor) can distort the electrical signals transmitted through the electrical path. Sixth, it is difficult to de-solder the lead of the resistor from the electrical path.

It is also known to use a probe tip that is not solder to the device to be tested. The problem with this method is that it is very difficult to consistently provide a mechanical connection between the probe tip and the device, which makes it very difficult to accurately and reliably test the electrical signals transmitted in the device to be tested.

### SUMMARY OF THE INVENTION

To overcome the problems described above, preferred embodiments of the present invention provide a probe tip that solves at least one of the above described problems.

According to a preferred embodiment of the present invention, a probe tip for attaching to a device to be tested includes a flexible circuit board, at least one contact pad arranged to be attached to at least one contact of a probe tip connector, at least one electrical component having first and second ends, and at least one test pad arranged to be attached to the device to be tested. The at least one contact pad is connected to the first end of the at least one electrical component, and the at least one test pad is connected to the second end of the at least one electrical component. Each of the electrical components of the probe tip is connected to at least one contact pad and is connected to at least one test pad.

The at least one electrical component is preferably a resistor. A stiffener is preferably attached to a portion of the flexible circuit board. The at least one electrical component is preferably located on or in a portion of the flexible circuit board which is located away from the portion of the flexible circuit board connected to the stiffener. Preferably, the probe tip includes at least one pair of electrical component pads, where the first end and the second end of the at least one electrical component are attached to corresponding pads of the at least one pair of electrical component pads.

The at least one electrical component is preferably attached to the surface of the flexible circuit board. The at least one electrical component is preferably provided on or in a layer within the flexible circuit board. The at least one contact pad and the at least one test pad are preferably located on opposing surfaces of the flexible circuit board. The at least one test pad preferably includes a pair of test pads that is arranged on opposing sides of the flexible circuit board and that is arranged such that heat applied to one pad of the pair of test pads is transferred to the other pad of the pair of test pads. The at least one test pad preferably includes a through hole.

Preferred embodiments of the present invention include a probe tip assembly that includes the probe tip discussed above and a probe tip connector including at least one contact. The at least one contact of the probe tip connector is attached to the at least one contact pad of the probe tip. The at least one contact is preferably soldered to the at least one contact pad.

Preferred embodiments of the present invention include a connector assembly that includes at least one probe tip assembly discussed above, a test equipment connector, and at least one cable connecting the at least one probe tip assembly and the test equipment connector. The connector assembly preferably includes a circuit board, where the at least one cable is attached to the circuit board and where the probe tip connector is attached to the circuit board. The connector assembly preferably includes a circuit board connector, where the circuit board connector connects the probe tip connector and the circuit board.

Preferred embodiments of the present invention include a testing assembly that includes a connector assembly discussed above, test equipment, and a device to be tested. The connector assembly connects the test equipment and the device to be tested.

Preferred embodiments of the present invention include a method of testing a device that includes providing the device, providing a probe tip that is connected to test equipment by a connector assembly, attaching the probe tip to the device, and testing the device. The probe tip includes a flexible circuit board.

The step of attaching preferably includes the step of soldering the probe tip to the device. After the step of testing, the probe tip is either removed from the device or is left on the device.

Other features, elements, characteristics and advantages of the present invention will become more apparent from the following detailed description of preferred embodiments of the present invention with reference to the attached drawings.

### BRIEF DESCRIPTION OF THE DRAWINGS

FIG. 1A is a perspective view of a connector assembly according to a preferred embodiment of the present invention.

FIG. 1B is a perspective view of a portion of the connector assembly shown in FIG. 1A.

FIG. 1C is a perspective view of a portion of the connector assembly shown in FIG. 1A.

FIG. 2A is a perspective view of a probe tip assembly according to a preferred embodiment of the present invention.

FIG. 2B is a side view of the probe tip assembly shown in FIG. 2A.

FIG. 3 is a perspective view of a probe tip according to a preferred embodiment of the present invention.

FIG. 4 is a top plan view of the probe tip shown in FIG. 3.

FIG. 5 is a bottom plan view of the probe tip shown in FIG. 3.

FIG. 6 is a side view of the probe tip shown in FIG. 3.

### DETAILED DESCRIPTION OF PREFERRED EMBODIMENTS

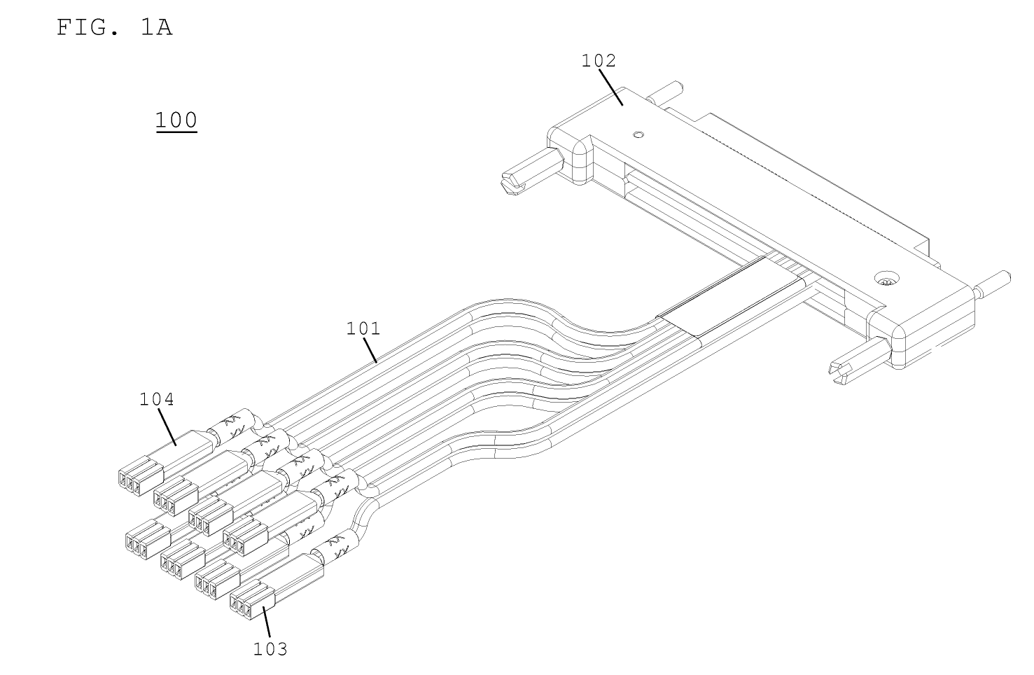

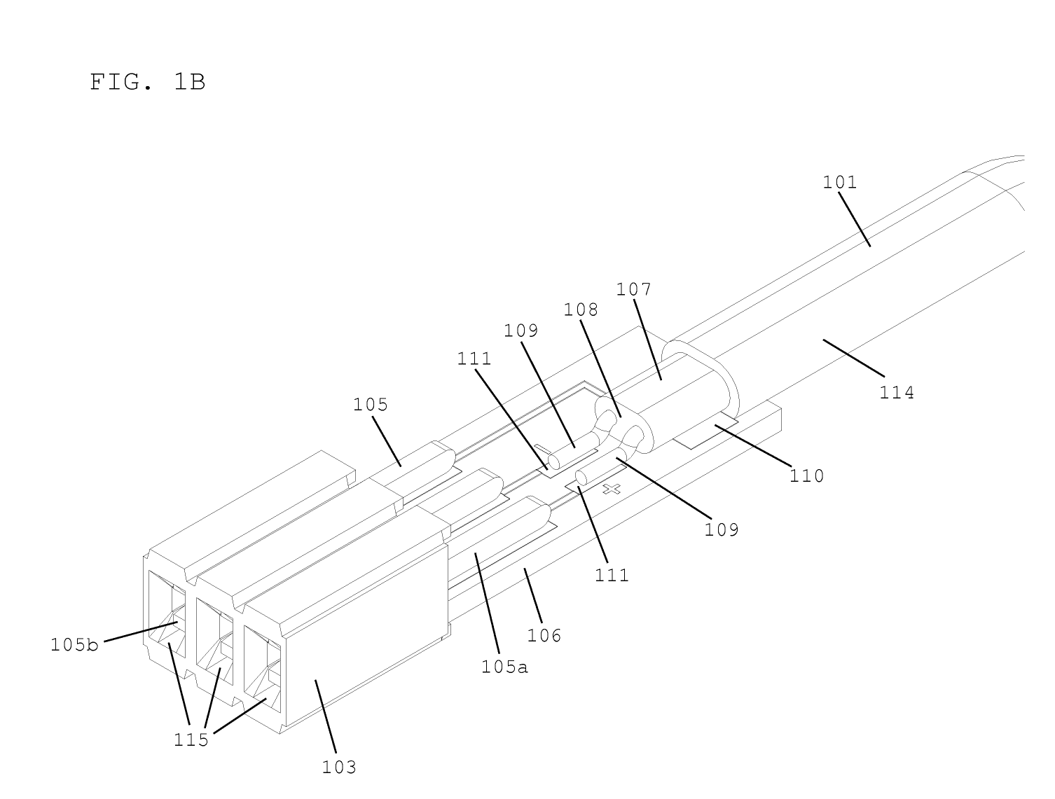

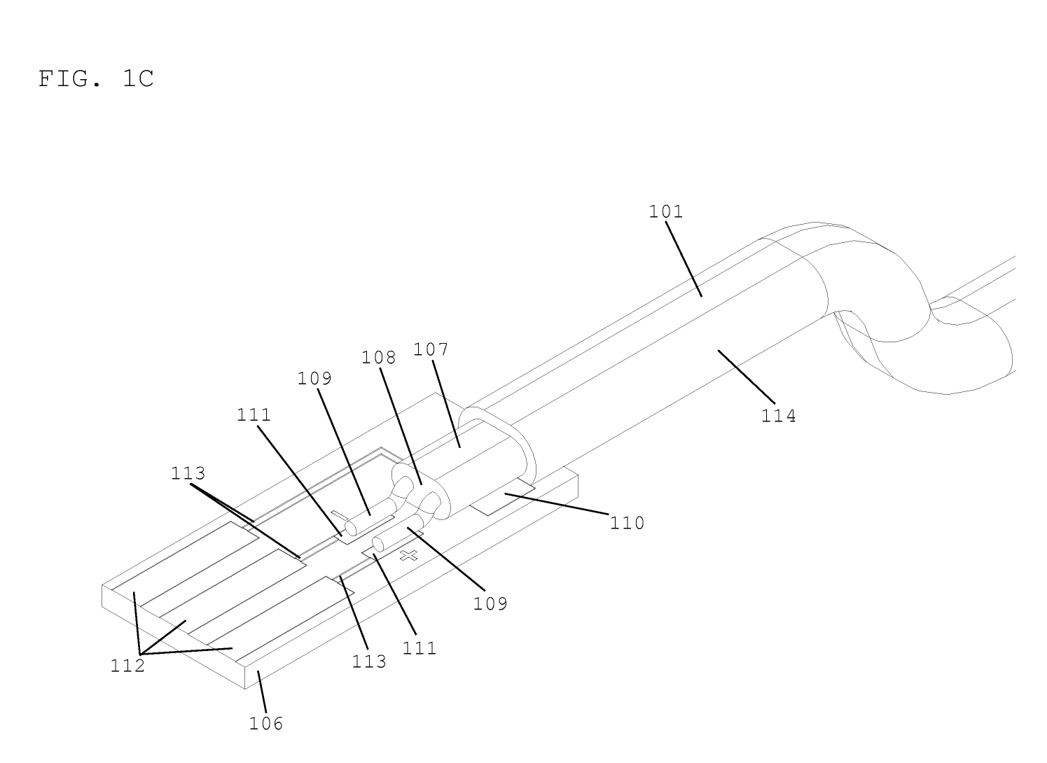

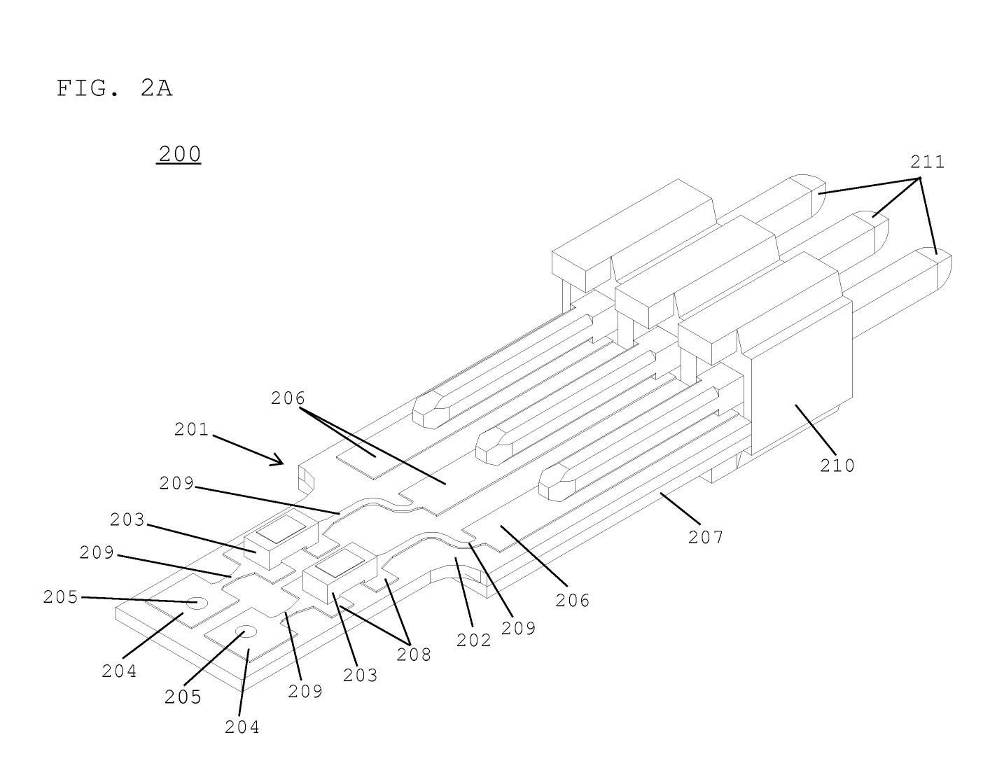

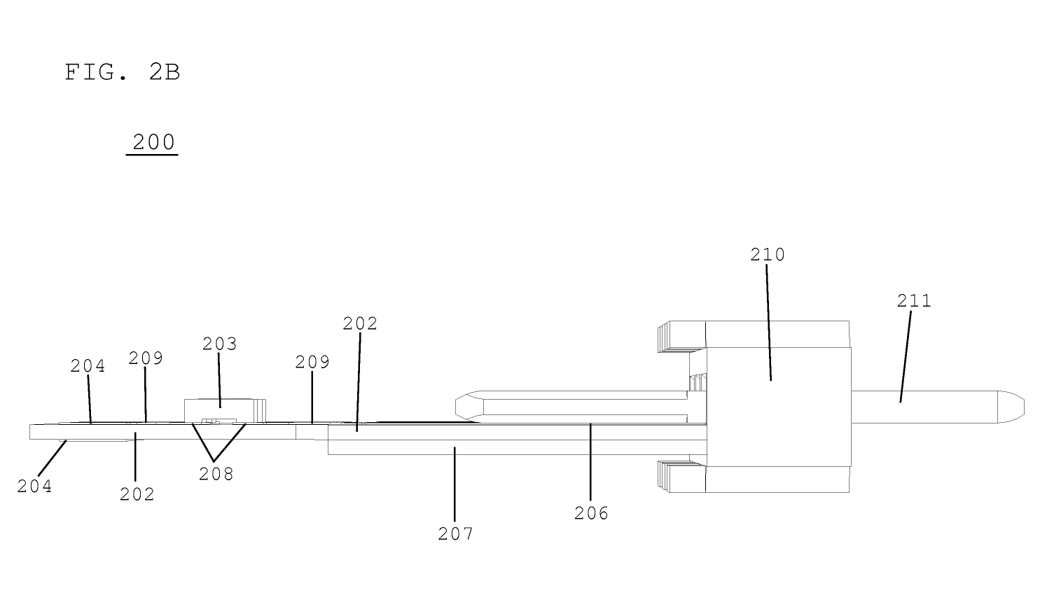

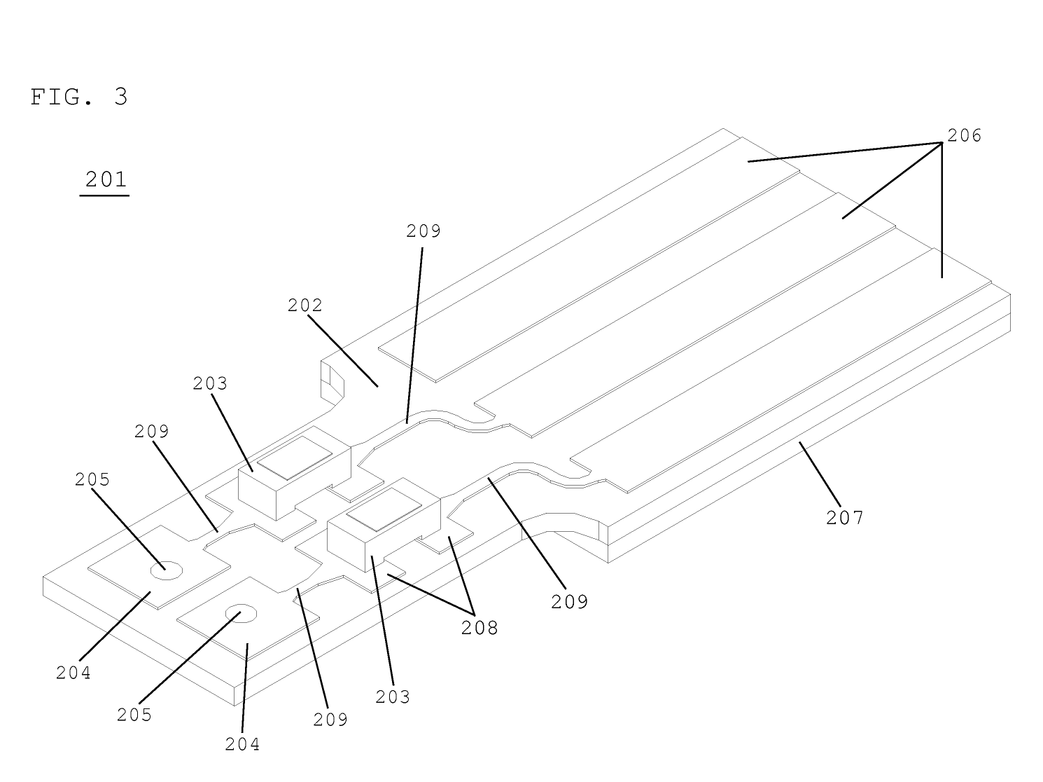

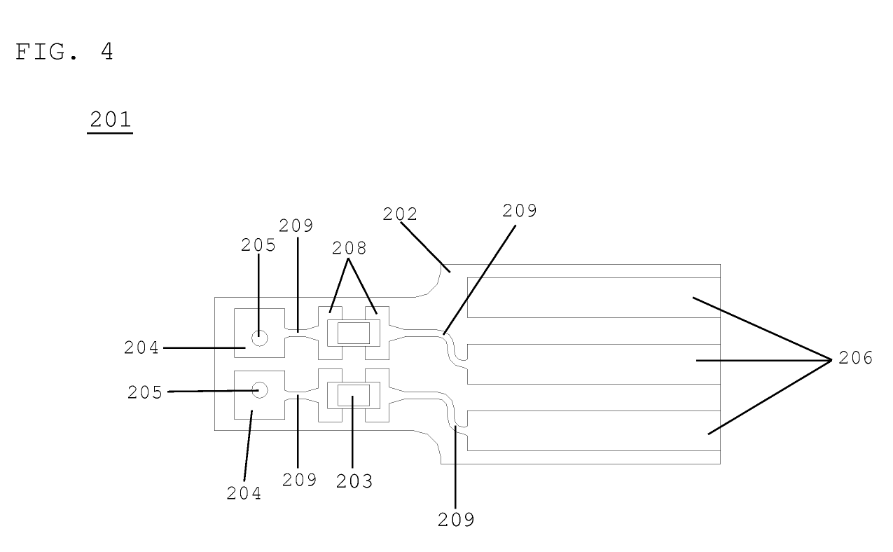

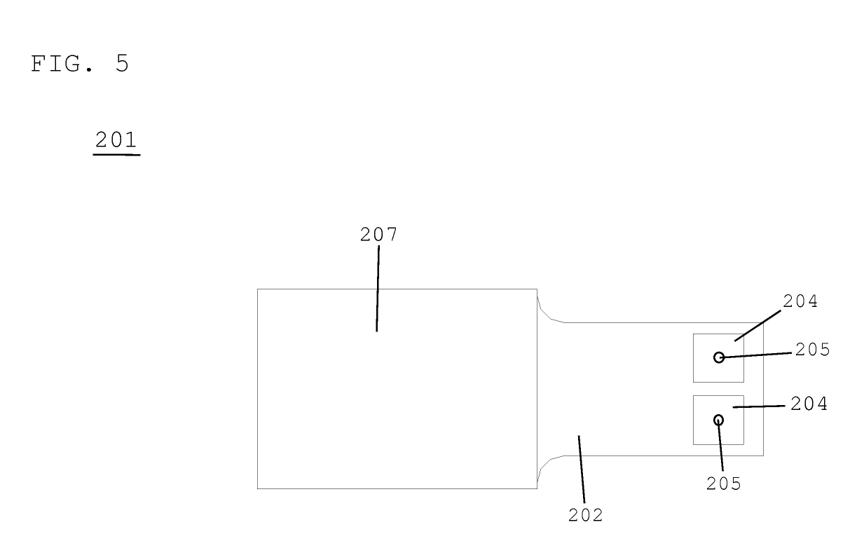

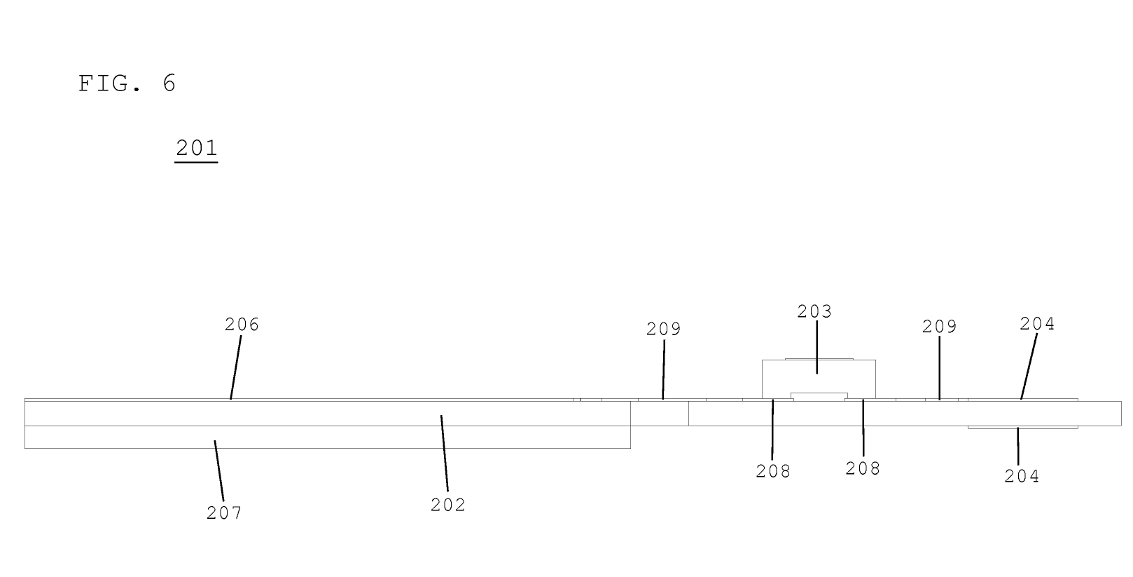

The present invention will be discussed with reference to FIGS. 1A-6. FIGS. 1A-1C show a connector assembly 100 according to a preferred embodiment of the present invention. FIGS. 2A and 2B show a probe tip assembly 200 according to a preferred embodiment of the present invention. FIGS. 3-6 show a probe tip 201 according to a preferred embodiment of the present invention.

FIG. 1A-1C show the connector assembly 100 according to a preferred embodiment of the present invention. The connector assembly 100 includes cables 101 that connect connector 102 with a plurality of female connectors 103. Connector 102 is connected to test equipment (not shown), which is used to test a device to be tested (not shown). The type of connector 102 used with the connector assembly 100 can be varied and will depend upon the type of test equipment used. Although only one connector 102 is shown in FIG. 1A, any number of connectors 102 can be used.

Preferably, cables 101 are twinax cables. However, any other suitable type of cable, e.g., coaxial cable or regular cable (a single conductor surrounded an insulator), can also be used. As seen in FIGS. 1B and 1C, cables 101 include conductors 109 that are surrounded by an inner insulator 108 that is further surrounded by a ground sheath 107 that is further surrounded by an outer insulator 114.

Each of the cables 101 is attached to a corresponding circuit board 106, as best seen in FIGS. 1B and 1C. The circuit board 106 preferably includes contact pads 112, traces 113, a ground pad 110, and signal pads 111. The signal pads 111 are connected to corresponding contact pads 112 by corresponding traces 113, and the ground pad 110 is connected to the remaining contact pad 112 by the remaining trace 112.

Preferably, as shown in FIGS. 1B and 1C, three contact pads 112, two signal pads 111, and one ground pad are used. However, the arrangement of contact pads 112, traces 113, ground pad 110, and signal pads 111 can be varied and will depend upon the type of cables used. For example, if coaxial cables are used, it is possible to use two contact pads 112, one signal pad 111, and one ground pad. Even if twinax cables are used, it is possible to use different arrangements. For example, instead of having the two contact pads 112 connected to the signal pads 111 located next to each other, it is possible to have the contact pad 112 connected to the ground pad 110 located between the two contact pads 112 connected to the signal pads 111.

Preferably, the conductors 109 and the ground sheath 107 are soldered to the signal pads 111 and the ground pad 110, respectively. However, any other suitable method of attaching the conductors 109 and the ground sheath 107 to the circuit board 106 can be used.

Connector assembly 100 preferably includes a plurality of female connector 103. Although eight female connectors 103 are shown in FIG. 1A, any number of female connectors 103 can be used. Each of the female connectors 103 includes contacts 105 that are attached to corresponding contact pads 112 on the circuit board 106. The contacts 105 of the female connector 103 include a tail portion 105a for attaching to the circuit board 106 and a head portion 105b for connecting to another contact, which will be discussed be below. The head portion of the contact 105 is preferably forked for receiving another contact between the forks. However, other suitable arrangements of the contact 105 can also be used.

Preferably, the contacts 105 are soldered to the corresponding contact pads 112 on the circuit board 106. However, any other suitable method can be used to attach the contacts 105 to the corresponding contact pads 112 on the circuit board 106. The contacts 105 are inserted into the cores 115 of the female connector 103. The number of cores 115 and the number of contacts 105 can be varied and will depend upon the type of cable used. The type of contact 105 can also be varied and will depend upon the type of connector used with the probe tip assembly 200, discussed below.

As shown in FIG. 1A, the circuit board 106 (not seen in FIG. 1A) is covered with heat shrink wrap 104 to protect the circuit board 106. Instead of heat shrink wrap 104, any other suitable covering can be used to protect the circuit board 106.

FIGS. 2A and 2B show the probe tip assembly 200 according to a preferred embodiment of the present invention. The probe tip assembly 200 includes a probe tip 201 and a male connector 210. The probe tip 201 includes a flexible circuit board 202 to which the male connector 210 is attached. Preferably, the contacts 211 are soldered to the flexible circuit board 202. However, any other suitable method can be used to attach the contacts 211 to the flexible circuit board 202.

The contacts 211 of male connector 210 are inserted into the cores 115 of the female connector 103 to engage the contacts 105 of the female connector 103 (not shown in FIGS. 2A and 2B). Of course, the gender of female connector 103 and male connector 210 can be reversed. That is, a male connector can be attached to circuit board 106, and a female connector can be attached to flexible circuit board 202.

The flexible circuit board 202 preferably includes contact pads 206, traces 209, resistor pads 208, and test pads 204. As seen in FIGS. 2A-4, the resistor pads 208 are arranged into pairs of resistors pads 208. A resistor 203 is attached to a corresponding pair of resistor pads 208. The test pads 204 are also arranged into pairs of test pads 204. The test pads 204 in a pair of test pads 204 are arranged on opposing sides of the flexible circuit board 202. Some of the traces 209 connect the contact pads 206 with one of the pair of resistor pads 208, and some of the traces 209 connect the test pads 204 that are located on the same side of the flexible circuit board 202 as the resistor pads 208 with the other of the pair resistor pads 208. The pair of test pads 204 are electrically connected to each other. It is preferable to cover the traces 209 with a protective layer (not shown).

An electrical path is provided between corresponding contact pads 206 and test pads 204 via a corresponding resistor 203. Preferably, the length of the electrical paths between each of the corresponding contact pads 206 and test pads 204 is the same or substantially the same so that the variation of the effect of the probe tip on the monitored and tested electrical signals is minimized. However, it is also possible that the length of the electrical paths between each of the corresponding contact pads 206 and test pads 204 is different. For example, if the flexible circuit board 202 has an L-shape (“right-angled”) (not shown) instead of the substantially rectangular shape shown in FIGS. 3-5, then the length of the electrical path between each of the corresponding contact pads 206 and test pads 204 can be varied. Even if the flexible circuit board 202 has an L-shape, it is still possible for the length of the electrical paths between each of the corresponding contact pads 206 and test pads 204 to be the same or substantially the same.

As shown in FIGS. 2A, 3, and 4, the contact pads 206, traces 209, resistor pads 208, and test pads 204 of the probe tip 201 are preferably arranged to provide two electrical paths that connect two contact pads 206 to two corresponding test pads 204. A third contact pad 206 is provided on the flexible circuit board 202 and is connected to the ground sheath 107 (shown in FIGS. 1B and 1C).

Preferably, as shown in FIGS. 2A and 2B, the flexible circuit board 202 uses three contact pads 206 and two pairs of test pads 204. The arrangement of the contact pads 206, traces 209, resistor pads 208, and test pads 204 can be varied and will depend upon the type of cables used. For example, if coaxial cables are used, it is possible to use two contact pads 206 and one pair of test pad 204. Even if twinax cables are used, it is possible to use different arrangements. For example, instead of having the two contact pads 206 connected to the pairs of test pads 204 next to each other, it is possible to have the contact pad 206 connected to the ground sheath 107 between the two contact pads 206 connected to the pairs of test pads 204.

Preferably, resistor 203 is a ceramic chip resistor. However, any other suitable resistor can also be used. It is also possible to embed the resistor in the flexible circuit board 202. No matter what type of resistor is used, it is preferable to locate the resistor as close to the test pad 204 as possible in order to minimize the electrical stub length of the probe tip 201. This arrangement of the resistor provides a consistently short electrical stub length. In certain applications, it may be desirable to use another type of electrical component, other than a resistor, in place of the resistor 203. These electrical components can include both passive and active components and can be attached to the surface of the flexible circuit board 202 or can be embedded within the flexible circuit board 202.

As seen in FIGS. 2A and 3-5, the pairs of test pads 204 are connected by a through hole 205 which extends from one side of the flexible circuit board 202 to the other side of the flexible circuit board 202. The sides of the through holes 205 are provided with a metal layer to ensure that an electrical path is provided between the pairs of test pads 204. Instead of using through holes 205 to connect the pairs of test pads 204, it is also possible to use vias. However, the through holes 205 allow greater and faster heat transfer when the probe tip 201 is soldered to a device to be tested (not shown). Typically, a probe tip 202 is placed on the device to be tested, and a soldering iron (not shown) is placed on the test pads 204 that are located on the same side of the flexible circuit board 205 as the contact pads 206. This enables each of the test pads 204 not located on the same side of the flexible circuit board 205 as the contact pads 206 to be soldered to the device to be tested at the same time. If the probe tip 201 is soldered to an electrical component (not shown) that is soldered to the device to be tested, it may be possible not to add any more solder and to use the solder attaching the electrical component to the device to be tested. The probe tip assembly 200 can be re-used by de-soldering the probe tip 201 from the device to be tested.

Preferably, the portion of the flexible circuit board 202 with the contact pads 206 is provided with a stiffener 207. The stiffener 207 and the contact pads 206 are provided on opposing sides of the flexible circuit board to assist in attaching the contacts 211 to the flexible circuit board 202.

It should be understood that the foregoing description is only illustrative of the present invention. Various alternatives and modifications can be devised by those skilled in the art without departing from the present invention. Accordingly, the present invention is intended to embrace all such alternatives, modifications, and variances that fall within the scope of the appended claims.

What is claimed is:

1. A probe tip for attaching to a device to be tested, comprising:
a flexible circuit board;
at least one contact pad arranged to be attached to at least one contact of a probe tip connector;
at least one electrical component having first and second ends; and
at least one test pad arranged to be attached to the device to be tested; wherein
the at least one contact pad is connected to the first end of the at least one electrical component;
the at least one test pad is connected to the second end of the at least one electrical component; and
each of the at least one electrical component of the probe tip is connected to at least one contact pad and is connected to at least one test pad.

2. A probe tip according to claim 1, wherein the at least one electrical component is a resistor.

3. A probe tip according to claim 1, wherein a stiffener is attached to a portion of the flexible circuit board.

4. A probe tip according to claim 3, wherein the at least one electrical component is located on or in a portion of the flexible circuit board which is located away from the portion of the flexible circuit board connected to the stiffener.

5. A probe tip according to claim 1, further comprising at least one pair of electrical component pads; wherein
the first end and the second end of the at least one electrical component are attached to corresponding pads of the at least one pair of electrical component pads.

6. A probe tip according to claim 1, wherein the at least one electrical component is attached to the surface of the flexible circuit board.

7. A probe tip according to claim 1, wherein the at least one electrical component is provided on or in a layer within the flexible circuit board.

8. A probe tip according to claim 1, wherein the at least one contact pad and the at least one test pad are located on opposing surfaces of the flexible circuit board.

9. A probe tip according to claim 1, wherein the at least one test pad includes a pair of test pads that is arranged on opposing sides of the flexible circuit board and that is arranged such that heat applied to one pad of the pair of test pads is transferred to the other pad of the pair of test pads.

10. A probe tip according to claim 1, wherein the at least one test pad includes a through hole.

11. A probe tip assembly comprising:
the probe tip according to claim 1; and
a probe tip connector including at least one contact; wherein
the at least one contact of the probe tip connector is attached to the at least one contact pad of the probe tip.

12. A probe tip assembly according to claim 1, wherein the at least one contact is soldered to the at least one contact pad.

13. A connector assembly comprising:
at least one probe tip assembly according to claim 11;
a test equipment connector; and
at least one cable connecting the at least one probe tip assembly and the test equipment connector.

14. A connector assembly according to claim 13, further comprising a circuit board; wherein
the at least one cable is attached to the circuit board; and
the probe tip connector is attached to the circuit board.

15. A connector assembly according to claim 14, further comprising a circuit board connector; wherein
the circuit board connector connects the probe tip connector and the circuit board.

16. A testing assembly comprising:
a connector assembly according to claim 13;
test equipment; and
a device to be tested; wherein
the connector assembly connects the test equipment and the device to be tested.

17. A method of testing a device comprising:
providing the device;
providing a probe tip that is connected to test equipment by a connector assembly;
attaching the probe tip to the device; and
testing the device; wherein
the probe tip includes a flexible circuit board.

18. A method according to claim 17, wherein the step of attaching includes the step of soldering the probe tip to the device.

19. A method according to claim 17, wherein, after the step of testing, the probe tip is removed from the device.

20. A method according to claim 17, wherein, after the step of testing, the probe tip is left on the device.
